(19) United States
(12) Patent Application Publication
(10) Pub. No.: US 2013/0239882 A1
(43) Pub. Date: Sep. 19, 2013

(54) COATED CRUCIBLE AND METHOD OF MAKING A COATED CRUCIBLE

(71) Applicants: Robert Billings Bramhall, JR., Gloucester, MA (US); Dane Fawkes, Amesbury, MA (US); Van Den Hock, Saratoga, CA (US)

(72) Inventors: Robert Billings Bramhall, JR., Gloucester, MA (US); Dane Fawkes, Amesbury, MA (US); Van Den Hock, Saratoga, CA (US)

(21) Appl. No.: 13/608,207

(22) Filed: Sep. 10, 2012

Related U.S. Application Data
(60) Provisional application No. 61/532,698, filed on Sep. 9, 2011.
(60) Provisional application No. 61/538,251, filed on Sep. 23, 2011.
(60) Provisional application No. 61/673,365, filed on Jul. 19, 2012.

(51) Int. Cl. C30B 11/00

(52) U.S. Cl. CPC C30B 11/002
USPC 117/223; 427/238; 427/237; 427/569

(57) ABSTRACT

A crucible for forming a boule in a portion of an interior volume of the crucible. The crucible has a crucible base material forming the interior volume. The crucible base material is separated from the boule by a barrier coat disposed between the boule and the crucible base material. The barrier coat has a pin free conformal thickness conforming to a surface of the crucible base material regardless of a shape of a surface feature on the surface, the barrier coat having a melting point higher than that of the boule.

### CROSS REFERENCE TO RELATED APPLICATIONS

This application claims the benefit of U.S. Provisional Application No.: 61/532,698, filed Sep. 9, 2011, U.S. Provisional Application No.: 61/538,251; filed Sep. 23, 2011 and U.S. Provisional Application No.: 61/673,365, filed Jul. 19, 2012.

### BACKGROUND

1. Field

The disclosed embodiment relate generally to a coated crucible and method of making a coated crucible and more specifically to a coated crucible and method of making a coated crucible used in a crystal growth apparatus.

2. Brief Description of Related Developments

Furnace systems, such as crystal growth systems and methods among other processes, are used as a manufacturing system and technique for the growth of crystals, such as sapphire or other crystals. Such systems may involve the placement of seed crystals in a crucible and the further placement of charge material in the crucible where the charge material is heated along with the seed crystal forming a melt while keeping a portion of the seed crystal intact. The melt is maintained at temperature for homogenization with the seed crystal and cooled in a controlled fashion to continually grow the seed crystal into a larger crystal. A problem arises where the crucible material may contaminate the crystal material during the melt process or otherwise. A further problem arises where the resulting larger crystal may be difficult to remove from the crucible upon cooling without undue difficulty and without destruction or damage to the crystal or the crucible. Accordingly, there is a desire for crystal growth systems that produce high purity crystals without undue damage and costs.

### BRIEF DESCRIPTION OF THE DRAWINGS

The foregoing aspects and other features of the embodiment are explained in the following description, taken in connection with the accompanying drawings.

FIG. 1 shows a diagram of an exemplary crystal growth system;

FIG. 2 shows a diagram of a crucible deposition system;

FIG. 3 shows diagram of a crucible deposition system;

FIG. 4 shows a top view of a crucible;

FIG. 5 shows a section view of a crucible;

FIG. 6 shows a section view of a crucible;

FIG. 7 shows a section view of a crucible;

FIG. 8 shows a partial section view of a crucible wall;

FIG. 9 shows a section view of a crucible;

FIG. 10 shows a partial section view of a crucible in a boule removal system;

FIG. 11 shows a diagram of a boule removal system; and

FIG. 12 shows a flow diagram.

### DETAILED DESCRIPTION OF THE EMBODIMENTS

Although the present embodiments will be described with reference to the embodiments shown in the drawings, it should be understood that the embodiments can be embodied in many alternate forms of embodiments. In addition, any suitable size, shape or type of elements or materials could be used.

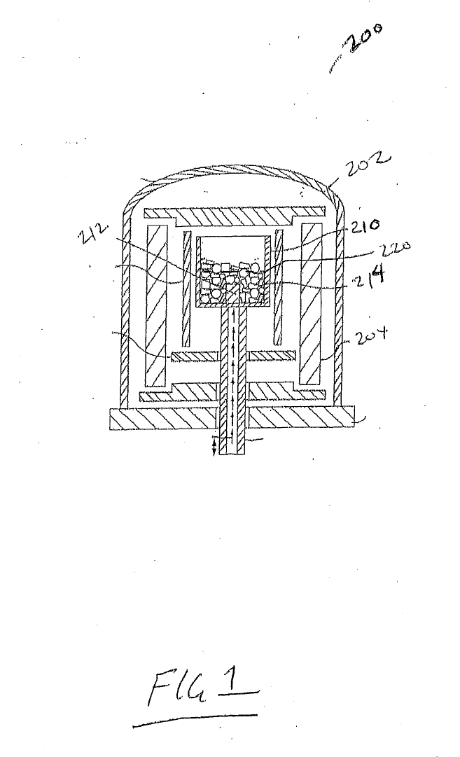

Referring now to FIG. 1, there is shown a crystal growth system 200 suitable for a manufacturing process using the present disclosed embodiments. The exemplary crystal growth system 200 may be a furnace used to grow a single crystal, for example, sapphire or otherwise. Crystal growth system 200 has a housing 202 forming a chamber which may be cooled as required during the crystal growth process. Within chamber 202 is an insulating element 204 and heating element 206 and crucible 210 where crucible 210 may have features as disclosed in greater detail below. By way of example, system 200 may have features as disclosed in United States Publication Number 2011/0179992A1 published Jul. 28, 2011 and entitled “Crystal Growth Methods and Systems” which is hereby incorporated by reference herein in its entirety. In operation, a seed crystal 212, for example, sapphire may be oriented as desired and placed at an interior on the bottom of crucible and surrounded and covered by charge material 214. The crucible is heated to slightly above melting temperature of the charge material for homogenization while keeping a portion of the seed material 212 intact. The bottom of the crucible 210 is cooled at a predetermined rate, for example, by extraction of the crucible 210 from the heating zone 206, or controllably cooling the bottom of the crucible or otherwise where a crystal is grown as the melt solidifies with the cooling rate as the temperature decreases ultimately forming a crystal boule 220 within crucible 210. In operation, the boule 220 may be removed from crucible 210 by either destroying crucible 210 or the crucible may be reusable enabling boule removal without destroying or damaging the crucible as will be described in greater detail below. Upon removal, the larger crystal boule 220 may be cored to produce a substantially cylindrical ingot and sliced or otherwise cut to produce wafers or other suitable shapes. With the disclosed embodiments and as will be described with respect to coated crucible 210, the cored ingot may be larger and producing higher yield as opposed to the use of an uncoated crucible.

The manufacture of sapphire boules takes place within furnace 200 at elevated temperatures of about 2200° C., for a length of time. The raw sapphire 214 is placed within molding crucible 210 having molybdenum base material, which in turn is mounted into a chamber 202 having a furnace module which has a controlled environment, for example, vacuum or inert environment and with controlled temperature. The molten material may react with the base material of an uncoated metal crucible to form a metal oxide where metal oxide from an uncoated crucible may dissolve and diffuse into the molten material. The melt of the sapphire during this process bonds its outer surface to the moly-oxide surface of an uncoated crucible, forming a solid bond. This strong bond requires the fracture of an uncoated molybdenum crucible to remove the sapphire boule 220. Also this metal oxide layer contaminates the initial outer area of the sapphire boule, effecting product yield. An uncoated crucible may also be lost in this process and only recovered as scrap material where the unit cost of a crucible is quite high. In the disclosed embodiments, crucible 210 may have a base material, for example molybdenum with one or more coats, for example, one or more barrier coatings. In one embodiment, a barrier coat consists of a (20 to 50 nm), ALD (Atomic Layer Deposition) coating. Here, the ALD barrier layer prevents the metal oxide cross contamination during the crystal growth process, effectively sealing the molybdenum wall from the sapphire boule. In alternate embodiments, one or more layers may be provided, for example one or more barrier layer(s) or a release layer(s) may be provided. By way of example, a molybdenum crucible embodiment may be provided having a barrier layer applied, such as a Ruthenium, Osmium, Rhodium and Iridium layer by an ALD, Plasma Enhanced ALD or other suitable process. By way of example, Ru with Plasma Enhanced ALD, using NH3 (ammonia) with Ru(EtCp)2 as precursor component from which the Ruthenium is extracted and layered down may be applied. As sapphire crystal growth has a relatively long process cycle, for example, 15 day crystal growth process, a low solubility coating having a higher melting point than the sapphire and being inert with respect to the sapphire crystal growth process may be provided, for example, by Ru or alternately any suitable noble metal having a higher melting point than sapphire or other crystal as required. Here, noble metals that have a much higher melting point than Aluminum Oxide (sapphire) do not readily oxidize with virtually no solubility or interaction within the crystal formation making them suitable for the long process times. However, bulk material, or full crucibles made from such metals, for example Ruthenium, Indium or Rhodium may be cost prohibitive in this size crucible. Further, as the crucible may be consumable, any precious metal applied may also be consumable. As a result, using an ultrathin coating or application of these rare metals offers a lower cost to the crucible coating compared to the fabrication of a noble metal crucible. An ALD process is a hermitic sealed, or a pin hole free coating, and provides complete coverage regardless of surface features. ALD can be as thin as 1 angstrom up to 1 micron or more given the process time. Here, the coating may be as thin as possible, but having a maximum thickness to prevent interaction between the molybdenum and sapphire boule. For example, a 20 nm-50 nm coating or otherwise may be applied, thinner for cost, thicker to reduce or stop interaction. In alternate embodiments, other surface plating methods may be used, for example electrochemical deposition or CVD, for example, up to 100 nm or otherwise or plating up to microns to get close to “pin-hole” free as possible or otherwise but using additional costly material as compared to the ALD process. An exemplary process for atomic layer deposition is disclosed in U.S. Pat. No. 6,656,835 Issued Dec. 2, 2003 to Marsh et al. and entitled “Process for low temperature atomic layer deposition of RH” which is hereby incorporated by reference herein in its entirety. Another exemplary process for atomic layer deposition is disclosed in Electrochemical and Solid-State Letters, 7 (4) C46-C48 (2004) by Kwon et al. and entitled “PLASMA-ENHANCED ATOMIC LAYER DEPOSITION OF RUTHENIUM THIN FILMS” which is hereby incorporated by reference herein in its entirety. Another exemplary process for atomic layer deposition is disclosed in Journal of The Electrochemical Society, 151 (8) G489-G492 (2004) by Aaltonen et al. and entitled “ATOMIC LAYER DEPOSITION OF IRIDIUM THIN FILMS” which is hereby incorporated by reference herein in its entirety. In alternate embodiments, any suitable Atomic Layer Deposition or deposition process may be provided.

In the embodiments shown, the barrier coat prevents the metal oxide cross contamination during the crystal growth process, effectively sealing the molybdenum wall from the sapphire boule. Here, molten material can react with an uncoated metal crucible to form a metal oxide. Alternately, an uncoated metal crucible can be oxidized by atmospheric exposure before being used in the crystal fabrication process. Metal oxide from an uncoated crucible can dissolve and diffuse into the molten material. During the formation of the Boule, the outer layer of the crystal becomes contaminated with this metal oxide. This contamination renders the contaminated part of the crystal unusable resulting in a lower final product yield. In one embodiment, the disclosed crucible 210 is provided with a barrier coating between the base material, for example, molybdenum or otherwise of crucible 210 and boule 220 where the barrier coating forms a protective layer on to the crucible surface to provide a barrier between the base metal or metal oxide on the surface of the base metal of crucible 210 and the crystal melt 220. This barrier coating may have a melting temperature higher that the highest temperature used in the crystal fabrication process to prevent the melting and subsequent mixing of the crucible coating material with molten crystal material. In one embodiment, the barrier coating is hermetic and pin hole free to prevent any interaction between the base material of crucible 210 and the crystal melt. Further, the solubility of the barrier coating in the crystal melt may be low to prevent contamination of the crystal melt with barrier coating material. The adhesion of the barrier coating to the crucible base material may be strong to prevent delamination of the barrier coating from the crucible base material during the crystal fabrication process, for example, where large changes in temperature are present. Here, the coefficients of thermal expansion of the barrier coating material and the crucible base material may be close and/or with a strong bond. One method of deposition of a barrier coating on the base material of crucible 210 may be ALD (Atomic Layer Deposition) as a deposition technique to deposit the barrier coating on the crucible base material surface. Here, ALD produces a pin-hole free surface barrier coating and produces a conformal film which has the ability to uniformly cover with a uniform thickness high aspect ratio voids, peaks and cracks in/on the surface of the crucible base metal. In alternate embodiments, processes like PDL, CVD, PECVD, PVD, ECD and Plasma Spray may be used with reduced barrier coating properties. A pin hole free conformal coating having a consistent thickness ensures that there is no chemical interaction between the crucible base material and the crystal melt or diffusion of crucible base material into the crystal melt.

Prior to deposition, for example, of an Ru coating by ALD or otherwise, the crucible may require cleaning and pre processing. Such cleaning at a minimum would remove particles and any organic material. Leaving the native Molybdenum oxide may not hinder the ALD applied coating and may actually help the bonding. If required, an in situ H2 plasma cleaning or reducing plasma could be applied to eliminate the native molybdenum oxide, directly followed by the ALD process, for example, without exposure to atmosphere in which the Molybdenum will start growing back its native oxide. Pre cleaning the Molybdenum crucible ensures that all particles have been removed from the surface and any organic contamination has been removed from the surface. The latter can be achieved by using an organic solvent, the former by applying ultrasound/mega sonic energy to the crucible during the cleaning with an organic solvent or other suitable method. The cleaning may be done in a cleanroom environment and after cleaning the crucible may either stay in a cleanroom environment or may be double bagged before leaving the cleanroom environment. The ALD coating may also be performed in a cleanroom environment. If required and in the case of metal, for example, (Ru, Ir, Rh, Os) ALD the molybdenum crucible may also be exposed to a hydrogen containing plasma before the ALD deposition is started. This will remove unwanted physically or chemically absorbed oxygen from the Molybdenum surface. Here, forming metal oxides (Mo, Ru, Ir, Rh and Os) may be avoided as these oxides decompose or evaporate at the temperature of the crystal growth process, for example, (˜2100 C) or otherwise. In alternate embodiments, any suitable cleaning and/or pre processing may be used.

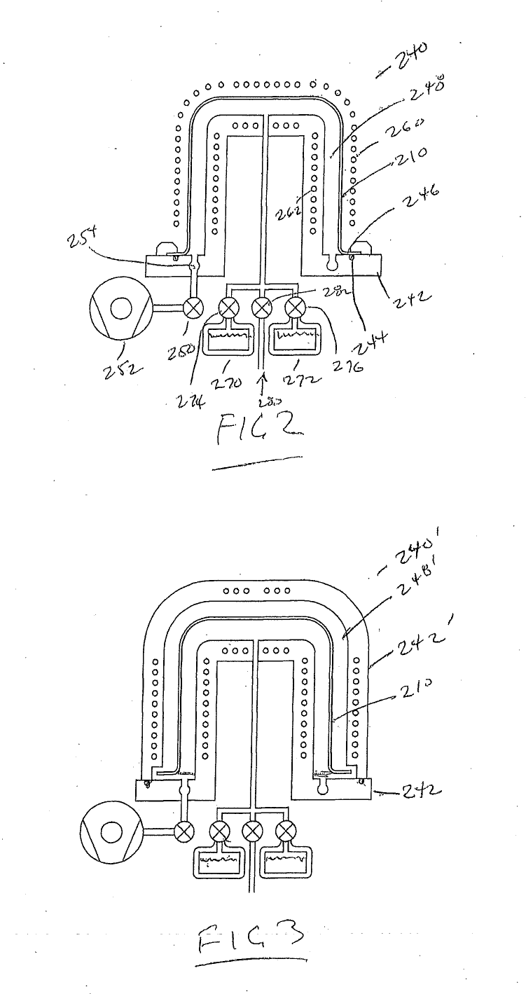

Referring now to FIG. 2, there is shown a diagram of a crucible deposition system 240 suitable for deposition of a barrier coating on crucible 210. Exemplary deposition system 240 is shown as an ALD system but may in alternate embodiments may be any suitable deposition system, for example, a plasma enhanced ALD system or otherwise. System 240 has chamber base 242 with seal 244 that seals against flange 246 of molybdenum crucible 210 where a sealed chamber region 248 is formed between an outer surface of base 242 and the interior surface of crucible 210. Vacuum pump 252 is connected to interior manifold 254 with isolation valve 250 where vacuum pump 252 may selectively evacuate the chamber region 248. Heater elements 260, 262 may apply heat to the chamber and/or crucible 210, for example, at 200 degree C. or otherwise as needed. Precursor 1 270 and precursor 2 272 are connected to chamber 248 by high speed pulse valves 274, 276 respectively to supply alternating vapor pulses in the ALD process. Vent or purge source 280 may be connected to chamber 248 by valve 282. System 240 may have features as ALD systems supplied by Cambridge Nanotech, Inc. or otherwise. In the embodiment shown, the crucible 210 lends itself to act as the vacuum chamber of the ALD system 240. By inverting the crucible 210 and sealing the open area 246 to an ALD/vacuum process module 248, the inside of the crucible 210 becomes the inside of the ALD process chamber 248. By applying controlled heat (thermal blanket) 260 to the exterior of the crucible and flowing the reactive gases inside the crucible 210, the ALD process will only deposit the desired film on the inside surface (i.e. the surface that will be exposed to the crystal melt) of the crucible 210. Here, for example and with the ALD process, each pair of sequential precursor gas pulses deposits a monolayer of film on the exposed crucible surface such that the thickness of the film may be precisely controlled such that a user may selectively provide n pairs of sequential precursor gas pulses to deposit a conformal layer of film having a thickness of the combined thickness of n monolayers of the film. Here, the deposition rate may be 1 nm or less or otherwise depending upon the thickness of each monolayer based on the material being deposited and the allowable timing of the sequential gas pulses. Crucibles may be fabricated from Molybdenum, for example, spun to form a bowl shape. Other (super) alloy and refractory metals may be used as alternative crucible materials. Precursor material producing Ruthenium or other suitable coating may be applied with the ALD process, for example, with a Plasma Enhanced ALD process or otherwise. The thermal stability at crystal melt process temperature is provided so that the deposited Ru does not melt or dissolve at crystal formation process temperatures. Coating thickness of 35 nm is a nominal ALD oxide process. In alternate embodiments, a thinner coating of 20 nm or less or a thicker coating of 50 nm or more or otherwise may be provided.

Referring now to FIG. 3, there is shown a diagram of a crucible deposition system 240′. System 240′ may have features as disclosed with respect to system 240 but where a secondary chamber portion 242′ is provided forming the outside portion of chamber 248′ where crucible 210 is completely enclosed within chamber 248′.

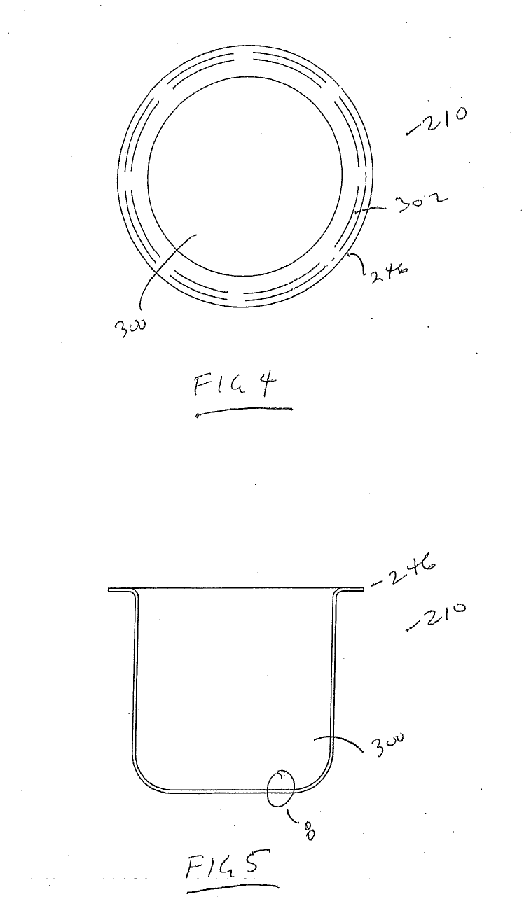

Referring now to FIG. 4, there is shown a top view of a crucible 210. Referring also to FIG. 5, there is shown a section view of a crucible 210. Crucible 210 is shown having melt containment portion and flange portion 246 with optional o-ring prepared sealing surface 302. In the disclosed embodiments, crucible 210 may have base material, such as molybdenum. An ALD barrier layer Ru coating may be provided to prevent cross contamination and metal oxide diffusion into the final crystal boule. Here, a single or multiple step process may be provided to build up the barrier layer. Here, an ALD (Atomic Layer Deposition) process may be used to barrier coat a molding crucible to prevent cross contamination and metal oxide diffusion into the final crystal substrate (Boule).

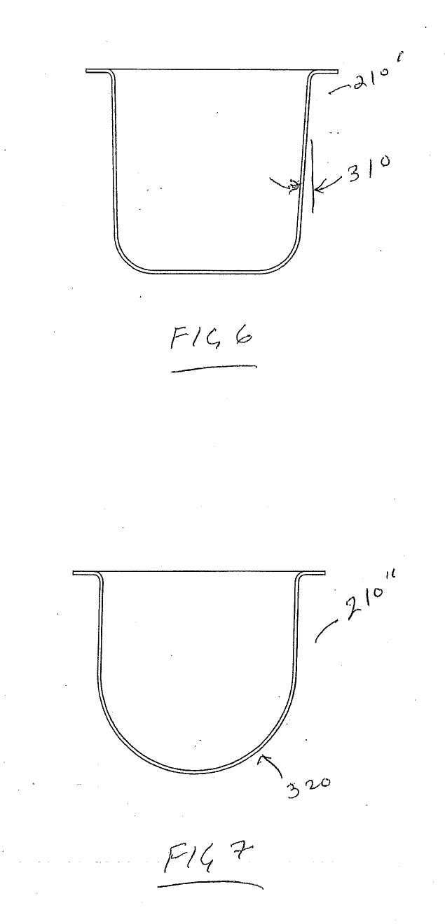

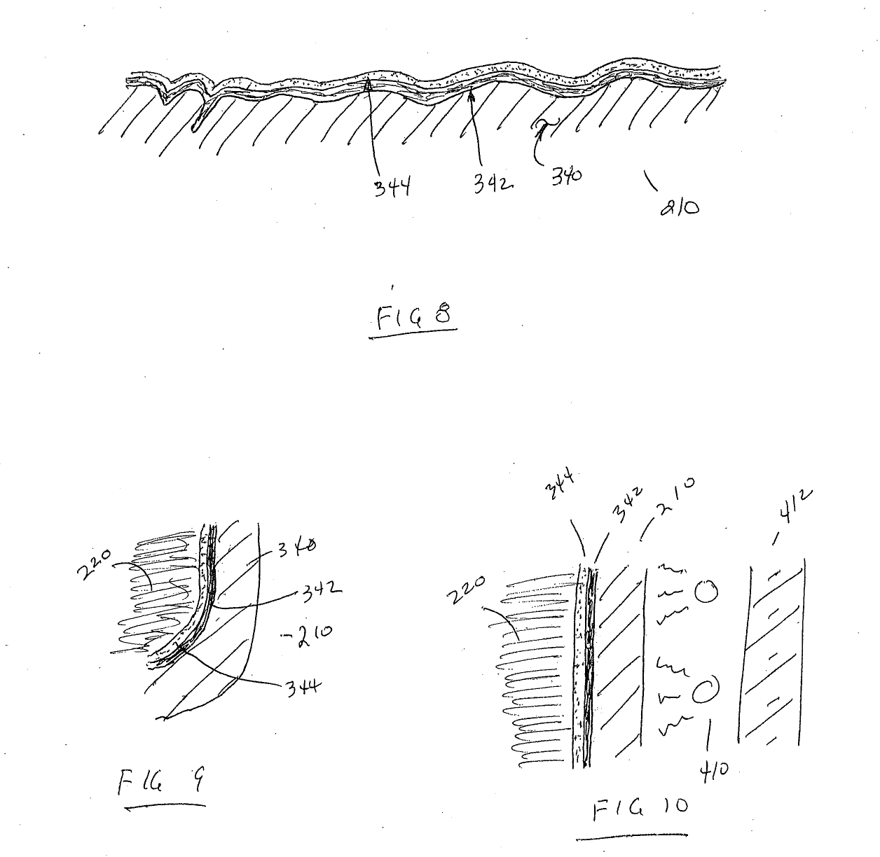

Referring now to FIG. 6, there is shown section view of an alternate embodiment crucible 210′ having draft angle 310. Referring also to FIG. 7, there is shown a section view of an alternate embodiment crucible 210″ having a full radius base 320.

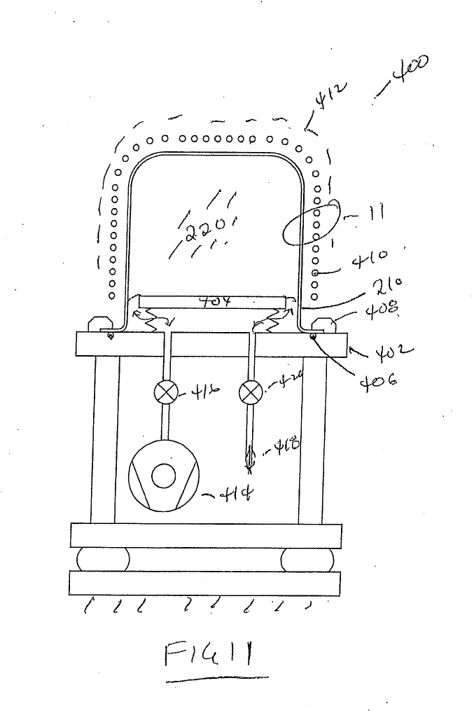

Referring now to FIG. 8, there is shown a partial section view of a crucible 210 wall. Referring also to FIG. 9, there is shown a section view of a crucible 210 with boule 220. In the embodiment shown, crucible 210 has base molybdenum material 340, native oxide 342, barrier ALD coating layer 344. As described, in alternate embodiments, native oxide 342 may be removed prior to deposition of barrier coating layer 344. In alternate embodiments, barrier coating layer 344 may have multiple layers, for example, a ZrO2 or other suitable first layer on the molybdenum or molybdenum oxide and a Ru or other suitable layer in contact with the boule. By way of further example where native oxide is not present or removed, the barrier coating may have two layers such as a top or outer coating 344 that is inert with respect to the melt and a second 342 diffusion or barrier coating deposited on the crucible (or on another layer or otherwise) to prevent reaction or inter diffusion between the crucible and the top or outer coating. In the embodiment shown, layer 344 is shown as a substantially conformal coating such that it conforms with uniform thickness with respect to the surface upon which it is deposited. Here, the barrier coat 344 is shown having a pin free conformal thickness conforming to a surface, for example, of the crucible base material or layer disposed thereon regardless of the shape of a surface feature on the surface.

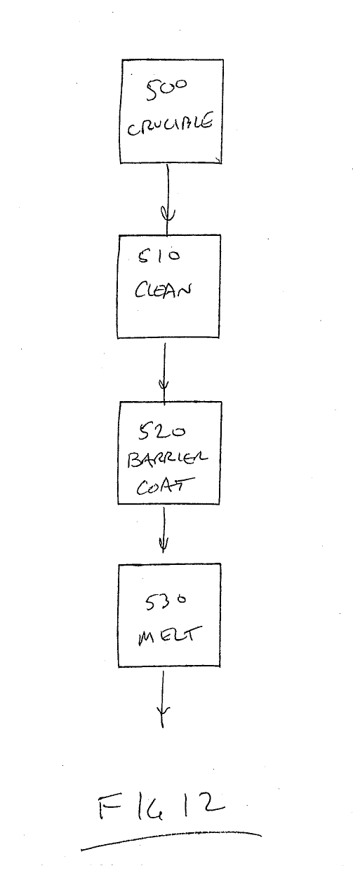

Referring now to FIG. 10, there is shown a partial section view of a crucible 210 in a boule removal system 400. Referring also to FIG. 11, there is shown a diagram of a boule removal system 400. Removal system 400 may have vibration surface, boule support surface 404, seal 406, clamps 408, heat source 410, insulation 412, pump 414, isolation valve 416, vent source 418 and/or vent valve 420. In operation, pump 414 may be a rotary vane dry pump producing a vacuum where, for example, with a 15″ crucible sealed to table 402 with sealing gasket 406, a 2500 pound or otherwise pulling force may be applied. Here, the vacuum sealing capabilities from the ALD process may be used to interface with seal 406. In alternate embodiments, pump 414 may be a pressure source, for example, to apply pressure within vessel 210 for expansion or otherwise. In the embodiment shown, system 400 may remove the boule 220 from crucible 210 without destruction of the crucible 210 making crucible 210 reusable by the nature of the release of boule 220 from crucible 210. Here, and upon completion and cooling the crucible 210/boule 220 combination is placed to removal table device 4000. The crucible 210 is inverted upside down, thus applying the weight of the boule as one of the removal forces. The exterior of the crucible is induction or radiation heated (IR or Quartz Lamp 410) to rapidly heat the metal crucible 210. The table applies a vertical vibration or ultra-sonic motion to release the boule. The heating of the crucible 210 expands outward. The combination of all three actions, vertical boule weight, high frequency vibration, thermal expansion results in a releasing of the boule 220. In alternate embodiments, any suitable combination of actions may be provided to release boule 220 from crucible 210.

Referring now to FIG. 13, there is shown a process flow diagram 490. Flow diagram 490 has a first step 500 of providing a molybdenum crucible, a second step 510 of cleaning, a third step 520 of applying a barrier coating and a fourth step 530 of forming a sapphire boule within the molybdenum crucible. In alternate embodiments, more or less steps may be provided.

In the disclosed embodiment, a crucible for forming a crystal boule in an interior volume of the crucible is provided where the crucible has a pinhole free non porous ALD, CVD or other suitably applied barrier coating on a surface of the interior volume with the barrier coating disposed between base material of the crucible and the boule and with the barrier coating having a melting point higher than the boule. The barrier coating is provided to prevent a reaction between the melt and the crucible. Here, the melt refers to the molten or liquid state from which the crystalline solid is formed by cooling or otherwise. This will enable the use of lower cost materials or materials that are more easily used to form a crucible for the manufacturing of the crucible. These materials meet all the requirements for the crucible except for the fact that these materials react with the melt, leading to contamination of the boule. In the case of some desirable coatings that are inert to the melt, there may be a reaction or inter diffusion between the material of the crucible and that coating. In this case a second coating (that may be referred to as a diffusion barrier coating) may be used that is deposited directly on to the surface of the crucible, for example, prior to depositing the top or outer coating (relative to the base material, said top or outer coating otherwise also referred to herein as the barrier coating) that is inert with respect to the melt. The diffusion barrier coating is provided for example to prevent a reaction or inter diffusion between the crucible and the top or outer coating. In alternate aspects of the disclosed embodiment, the coating techniques may be applied to any suitable combination of crystal application types, crucible materials and ancillary parts exposed to temperature in the crystal fabrication process. Here, a single or multilayer coating may be applied in any suitable crystal fabrication process to protect a crucible or other pieces exposed to liquid or gaseous material during the process of growing single or polycrystalline materials. Here, the top or outer coating may be of a material that is inert to the liquid or gaseous phase of the crystal growth material. Further and if needed, there may be a layer in between the crucible or other pieces and the top or outer coating to prevent a reaction or interdiffusion of the coated material and the top or outer coating material. Further, the top or outer coating material may also have “release layer” properties (or a further material or layer in addition to the top or outer coating may be provided) enabling easy separation of the crucible and the crystal after the crystal growth process has been completed. Accordingly the disclosed embodiment is intended to embrace all such alternatives. By way of example, the disclosed embodiment may be used in crystal growth applications, for example, gallium nitride (GaN), aluminum nitride (AlN), indium gallium nitride (InGaN), indium gallium aluminum (InGaAl), silicon carbide (SiC), silicon (Si), zinc oxide (ZnO), sapphire (Al2O3), calcium fluoride (CaF2), sodium iodide (NaI) and other halide group salt crystals, germanium, polysilicon, gallium arsenide (GaAs), YBCO, metal oxide single crystals or any suitable crystal. Accordingly, the disclosed embodiment may be used in combination with any suitable crystal combination. The disclosed embodiment may be used in combination with crucibles of different materials, such as metal, for example refractory metal or other crucibles made from tungsten (W), molybdenum (Mo), niobium (Nb), lanthanum (La), tantalum (Ta), rhenium (Re), Iridium or any suitable metal or metal alloys. By way of further example, the top or outer coating may be any suitable material, for example, any material described in the instant application or materials such as copper, molybdenum, tantalum, tungsten or any suitable material having a higher melting point than the melt and being inert with respect to the melt and applied by ALD, CVD, ECD, thermal spraying or any suitable coating method and where the top or outer coating may be conformal in thickness with respect to the surface deposited on and substantially pin hole free. By way of further example, the disclosed embodiment may be used in combination with crucibles of different materials, such as Al2O3, Gold, SnO2, MgO, FZY, graphite, clay graphite, silicon carbide, AlN, Si3N4, quartz, refractory nitrides, carbides, TAC, pyrolytic boron nitride or any suitable material. Accordingly, the disclosed embodiment may be used in combination with any suitable crucible combination. By way of example, the disclosed embodiment may be used in combination with an iridium (melting point of 2446 C) or other suitable crucible used in the fabrication of metal oxide single crystals such as sapphire, YAG or otherwise. By way of further example, the disclosed embodiment may be used in combination with a quartz or pyrolytic boron nitride or other suitable crucible used in combination with the fabrication of polysilicon. By way of further example, the disclosed embodiment may be used in combination with a quartz or AlN or Si3N4 or other suitable crucible used in combination with the fabrication of GaAs. Accordingly any suitable combination of crystal applications, with suitably coated crucibles used in the fabrication thereof. Further, the disclosed embodiment may be used in application of coating components used in the crystal fabrication process. By way of example, the disclosed embodiment may be used in combination with coating components associated with crystal fabrication such as heaters, liners, heat insulated barrel cylinders, reflection shields, supports, cover plates, housings, gradient control devices, coolant interface components, thermal break components, seed cooling components or any associated component within the crystal fabrication process. Accordingly all such alternatives are embraced.

In accordance with an exemplary embodiment, a reusable crucible for forming a boule in a portion of an interior volume of the crucible is provided. The crucible has a crucible base material forming the interior volume. A barrier coat disposed on the base material so the crucible base material is separated from the boule by a barrier coat disposed between the boule and the crucible base material. The barrier coat has a pin free conformal and uniform thickness conforming to a surface of the crucible base material regardless of a shape of a surface feature on the surface, the barrier coat having a melting point higher than that of the boule.

In accordance with another aspect, the surface comprises a diffusion barrier coat disposed between the barrier coat and the crucible base material. The diffusion barrier coat prevents inter diffusion between the barrier coat and the crucible base material.

In accordance with another aspect, the barrier coat has a thickness being a selectable n monolayers thick.

In accordance with another aspect, the barrier coat is substantially insoluble with respect to the boule.

In accordance with another aspect, the barrier coat has a thickness sufficient to prevent interaction between the boule and the crucible base material.

In accordance with another aspect, the barrier coat has a thickness less than 500 nm.

In accordance with another aspect, the barrier coat is provided on the crucible base material with the absence of a native oxide between the barrier coat and the crucible base material.

In accordance with another aspect, a crucible for forming a sapphire boule in a portion of an interior volume of the crucible is provided. The crucible has a molybdenum base material forming the interior volume. A noble metal barrier coat disposed on the molybdenum base material so that the molybdenum base material is separated from the sapphire boule by the noble metal barrier coat disposed between the sapphire boule and the molybdenum base material. The noble metal barrier coat has a pin free, non porous and uniform conformal thickness conforming to a surface of the crucible base material, the noble metal barrier coat having a melting point higher than that of the sapphire boule.

In accordance with another aspect, the surface comprises a diffusion barrier coat disposed between the noble metal barrier coat and the molybdenum base material. The diffusion barrier coat prevents inter diffusion between the noble metal barrier coat and the molybdenum base material.

In accordance with another aspect, the noble metal barrier coat has a thickness being a selectable n monolayers thick.

In accordance with another aspect, the noble metal barrier coat is substantially insoluble with respect to the sapphire boule.

In accordance with another aspect, the noble metal barrier coat has a thickness sufficient to prevent interaction between the sapphire boule and the molybdenum base material.

In accordance with another aspect, the noble metal barrier coat has a thickness less than 500 nm.

In accordance with another aspect, the noble metal barrier coat is provided on the molybdenum base material with the absence of a native oxide between the noble metal barrier coat and the molybdenum base material.

In accordance with another aspect, a method of forming a crucible, the crucible for forming a boule in a portion of an interior volume of the crucible, is provided. The method comprises providing a crucible base material; cleaning the crucible base material; and coating a barrier coat on at least a portion of the crucible base material, the barrier coat having a pin free, conformal and uniform thickness conforming to a surface of the crucible base material regardless of a shape of a surface feature on the surface, the barrier coat having a melting point higher than that of the boule.

In accordance with another aspect, cleaning the crucible base material comprises removing a native oxide from the crucible base material in situ with the coating. The barrier coat is provided on the crucible base material with the absence of the native oxide between the barrier coat and the crucible base material.

In accordance with another aspect, the crucible base material forms at least a portion of a vacuum chamber while coating.

In accordance with another aspect, coating comprises coating with atomic layer deposition.

In accordance with another aspect, coating comprises coating with plasma enhanced atomic layer deposition.

In accordance with another aspect, coating comprises coating with carbon vapor deposition.

It should be understood that the foregoing description is only illustrative of the invention. Various alternatives and modifications can be devised by those skilled in the art without departing from the invention. Accordingly, the present invention is intended to embrace all such alternatives, modifications and variances.

What is claimed is:

1. A reusable crucible for forming a boule in a portion of an interior volume of the crucible, the crucible comprising:
a crucible base material forming the interior volume;
a barrier coat disposed on the base material so that the crucible base material is separated from the boule by the barrier coat disposed between the boule and the crucible base material; and
the barrier coat having a pin free conformal and uniform thickness conforming to a surface of the crucible base material regardless of a shape of a surface feature on the surface, the barrier coat having a melting point higher than that of the boule.

2. The crucible of claim 1 wherein the surface comprises a diffusion barrier coat disposed between the barrier coat and the crucible base material, wherein the diffusion barrier coat prevents inter diffusion between the barrier coat and the crucible base material.

3. The crucible of claim 1 wherein the barrier coat has a thickness being a selectable n monolayers thick.

4. The crucible of claim 1 wherein the barrier coat is substantially insoluble with respect to the boule.

5. The crucible of claim 1 wherein the barrier coat has a thickness sufficient to prevent interaction between the boule and the crucible base material.

6. The crucible of claim 1 wherein the barrier coat has a thickness less than 500 nm.

7. The crucible of claim 1 wherein the barrier coat is provided on the crucible base material with the absence of a native oxide between the barrier coat and the crucible base material.

8. A crucible for forming a sapphire boule in a portion of an interior volume of the crucible, the crucible comprising:
a molybdenum base material forming the interior volume;
a noble metal barrier coat disposed on the molybdenum base material so that the molybdenum base material is separated from the sapphire boule by the noble metal barrier coat disposed between the sapphire boule and the molybdenum base material; and
the noble metal barrier coat having a pin free, non porous and uniform conformal thickness conforming to a surface of the crucible base material, the noble metal barrier coat having a melting point higher than that of the sapphire boule.

9. The crucible of claim 8 wherein the surface comprises a diffusion barrier coat disposed between the noble metal barrier coat and the molybdenum base material, wherein the diffusion barrier coat prevents inter diffusion between the noble metal barrier coat and the molybdenum base material.

10. The crucible of claim 8 wherein the noble metal barrier coat has a thickness being a selectable n monolayers thick.

11. The crucible of claim 8 wherein the noble metal barrier coat is substantially insoluble with respect to the sapphire boule.

12. The crucible of claim 8 wherein the noble metal barrier coat has a thickness sufficient to prevent interaction between the sapphire boule and the molybdenum base material.

13. The crucible of claim 8 wherein the noble metal barrier coat has a thickness less than 500 nm.

14. The crucible of claim 8 wherein the noble metal barrier coat is provided on the molybdenum base material with the absence of a native oxide between the noble metal barrier coat and the molybdenum base material.

15. A method of forming a crucible, the crucible for forming a boule in a portion of an interior volume of the crucible, the method comprising:
providing a crucible base material;
cleaning the crucible base material; and
coating a barrier coat on at least a portion of the crucible base material, the barrier coat having a pin free, conformal and uniform thickness conforming to a surface of the crucible base material regardless of a shape of a surface feature on the surface, the barrier coat having a melting point higher than that of the boule.

16. The method of forming a crucible of claim 15, wherein cleaning the crucible base material comprises removing a native oxide from the crucible base material in situ with the coating wherein the barrier coat is provided on the crucible base material with the absence of the native oxide between the barrier coat and the crucible base material.

17. The method of forming a crucible of claim 15, wherein the crucible base material forms at least a portion of a vacuum chamber while coating.

18. The method of forming a crucible of claim 15, wherein coating comprises coating with atomic layer deposition.

19. The method of forming a crucible of claim 15, wherein coating comprises coating with plasma enhanced atomic layer deposition.

20. The method of forming a crucible of claim 15, wherein coating comprises coating with carbon vapor deposition.
